(19) United States
(12) Patent Application Publication
(10) Pub. No.: US 2026/0276601 A1
(43) Pub. Date: Sep. 17, 2026

(54) SOLIDLY-MOUNTED ACOUSTIC BIOSENSOR

(71) Applicant: National Technology & Engineering Solutions of Sandia, LLC, Albuquerque, NM (US)

(72) Inventors: Darren Waltz Branch, Albuquerqeu, NM (US); Matthew Jones, Durham, NC (US)

(73) Assignee: Resonatia Diagnostics, Durham, NC (US)

(21) Appl. No.: 19/254,784

(22) Filed: Jun. 30, 2025

Related U.S. Application Data
(63) Continuation-in-part of application No. 18/226,946, filed on Jul. 27, 2023.

(51) Int. Cl. G01N 29/24; G01N 29/28; H10N 30/063; H10N 30/067

(52) U.S. Cl. CPC G01N 29/245; G01N 29/28; H10N 30/063; H10N 30/067; G01N 2291/02466; G01N 2291/0255; G01N 2291/101

(57) ABSTRACT

A solidly-mounted lateral field excitation sensor is described. The sensor includes a relatively thin layer of lithium niobate layered on a solid substrate (such as a silicon substrate). The sensor also includes a row of interdigital metallic fingers formed on the layer of lithium niobate. An active region of the sensor includes the row of interdigital metallic fingers and lithium niobate underlying the metallic fingers.

### RELATED APPLICATION

This application is a continuation in part of U.S. patent application Ser. No. 18/226,946, filed on Jul. 27, 2023, and entitled “ACOUSTIC BIOSENSOR.” The entirety of this application is incorporated herein by reference.

### STATEMENT OF GOVERNMENT INTEREST

This invention was made with Government support under Contract No. DE-NA0003525 awarded by the United States Department of Energy/National Nuclear Security Administration. The U.S. Government has certain rights in the invention.

### TECHNICAL FIELD

The concepts presented herein relate to acoustic biosensors and applications of acoustic biosensors. More specifically, the technologies described herein relate to an acoustic biosensor that is usable to detect a microbial. Even more specifically, the technologies described herein relate to an acoustic biosensor that is usable to detect an interaction between a microbial and an antimicrobial, such that a determination can be made as to effectiveness of the antimicrobial in treating/inhibiting the microbial.

### BACKGROUND

Biosensors are useful for a variety of applications including drug discovery, disease detection, environmental monitoring (e.g., atmospheric conditions, water quality, and/or soil quality), food quality monitoring, and prosthetic devices. Conventional biosensors are capable of detecting biological and/or chemical reactions in a sample.

A biosensor can be configured based on a type of analyte chosen that is to be detected (e.g., blood glucose for monitoring blood glucose concentrations, human chorionic gonadotropin (hCG) for pregnancy tests, a prostate specific antigen (PSA) for prostate cancer, cardiac troponin I (CTnI) for myocardial infarction, amongst others). Conventional biosensors, however, detect presence of an analyte of interest, but do not provide any indication as to treatment with respect to the analyte. For example, a conventional biosensor may inform a test subject that the subject has bacterial pneumonia but does not provide any information with respect to treatment of the bacterial pneumonia.

Further, biosensors have conventionally been relatively expensive to manufacture; for example, a conventional biosensor requires etching on both sides of a wafer prior to being released, so that the resultant biosensor is a relatively thin membrane. Such a process can be difficult to repeat, resulting in lower than desirable yield.

### SUMMARY

The following is a brief summary of subject matter that is described in greater detail herein. This summary is not intended to be limiting as to the scope of the claims.

Described herein are various technologies related to a solidly-mounted acoustic biosensor (a lateral field excitation sensor), where such biosensor is manufacturable using conventional semiconductor manufacturing techniques and does not require backside etching or release of a thin membrane from the underlying silicon substrate. The biosensor exhibits relatively high performance characteristics, including a quality factor that is at or above 200 when the biosensor is positioned in air and above 100 when the biosensor is positioned in water.

The acoustic biosensor includes a solid substrate (e.g., a silicon substrate) that has a layer of lithium niobate thereon. The lithium niobate can be Y-cut lithium niobate or X-cut lithium niobate. The layer of lithium niobate is relatively thin, such as between 1 micron and 20 microns thick. The acoustic biosensor includes an active region, where the active region comprises a row of metallic interdigital fingers. Optionally, the acoustic biosensor includes two rows of metallic interdigital fingers, where the rows are in parallel with one another. The row of interdigital fingers includes between 20 and 400 fingers. The row of fingers includes two comb-like structures that are opposing one another, such that fingers of a first comb-like structure point towards a second comb-like structure and fingers of the second comb-like structure point towards the first comb-like structure. The fingers of the comb-like structures are in parallel with one another, where fingers of the first comb-like structure overlap in space with fingers of the second comb-like structure laterally but do not overlap longitudinally.

The interdigital fingers can be any suitable material, such as titanium, aluminum, copper, etc. In an example, the interdigital fingers include a layer of titanium and a layer of aluminum, where the layer of titanium is in contact with the lithium niobate. The biosensor also optionally includes a layer of oxide or polymer on the interdigital fingers.

In operation, a sample is introduced to the biosensor, where the sample is directed towards the active region of the biosensor (which includes the row of interdigital fingers formed on the lithium niobate). Fungi, bacteria, or the like in the sample covalently attaches to the surface of the interdigital fingers through antibodies or receptors. In an example, the sample includes bacteria. Subsequent to the bacteria attaching to the surface of the interdigital fingers, an antibiotic can be introduced to the sample, which may cause the bacteria to detach from the surface, degrade, etc., which in turn forms an acoustic mode in the lithium niobate. Lithium niobate is a piezoelectric material, and accordingly the acoustic mode results in an electrical signal, which is read out from the biosensor. A processing system receives the electrical signal and outputs data that is indicative of an interaction between the bacteria and the antibiotic (or more broadly, between a microbial and an antimicrobial in the sample).

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such devices, systems, and/or methods. Its sole purpose is to present some concepts in a simplified form as a prelude to the more detailed description that is presented later.

### BRIEF DESCRIPTION OF THE DRAWINGS

FIG. 1 is a schematic profile view of an acoustic biosensor.

FIG. 2 is a schematic overhead view of an acoustic biosensor.

FIG. 3 is an enlarged view of an active region of an acoustic biosensor.

FIG. 4 is another enlarged view of an active region of an acoustic biosensor.

FIGS. 5 and 6 are schematics that illustrate processing steps for manufacturing an acoustic biosensor.

FIG. 7 is a functional block diagram of a system that includes an acoustic biosensor.

FIG. 8 is a flow diagram illustrating a method for manufacturing an acoustic biosensor.

FIG. 9 is a flow diagram illustrating a method for operating an acoustic biosensor.

FIG. 10 is a schematic depicting a computing system.

### DETAILED DESCRIPTION

Various technologies pertaining to acoustic biosensors are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details.

In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Moreover, the term “or” is intended to mean an inclusive “or” rather than an exclusive “or.” That is, unless specified otherwise, or clear from the context, the phrase “X employs A or B” is intended to mean any of the natural inclusive permutations. Hence, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

As used herein, the phrase “at least one of” is intended to be inclusive of a variety of possible alternatives. For example, “at least one of A, B, and C” means any possible combination of A alone, B alone, C alone, A and B together, B and C together, A and C together, or A, B, and C together. It is intended that the same is true of the phrase “at least one of A, B, or C.”

Ranges can be expressed herein as from “about” a value to “about” another value. The term “about,” and other related terms of approximation, are understood to encompass variations of +/−10% or less, preferably +/−5% or less, more preferably +/−1% or less, and still more preferably +/−0.1% or less from the specified value, insofar such variations are appropriate to perform in the disclosed application.

Described herein are various technologies pertaining to acoustic biosensors that detect microbials, antimicrobials, and/or biomarkers (e.g., analyte(s) of interest). The acoustic biosensors described herein can also be configured to detect interactions between microbials and antimicrobials. The acoustic biosensors described herein further output information that is indicative of existence of microbials, antimicrobials, biomarkers, and/or interactions between microbials and antimicrobials. The interactions can be physical and/or chemical (such as, by way of nonlimiting example only, the inhibition of cell wall synthesis, protein synthesis, or DNA synthesis; or the disruption of a membrane function). An acoustic biosensor includes an active region that comprises a layer of piezoelectric material (e.g., lithium niobate) that is layered upon a solid (e.g., silicon) substrate. The active region also includes a row of metallic interdigital fingers. The active region is configured to receive a sample, where, in an example, the sample includes a microbial and an antimicrobial. The acoustic biosensor further includes an electrode that is in contact with the layer of piezoelectric material. The acoustic biosensor detects an interaction between the microbial and the antimicrobial in the sample. More specifically, an acoustic mode is generated in the piezoelectric material, where the acoustic mode is caused by an interaction between the microbial and the antimicrobial. The acoustic biosensor outputs an electrical signal by way of the electrode based upon the acoustic mode, where the electrical signal is indicative of a physical, chemical, and/or electrical interaction between the microbial and the antimicrobial. By way of a nonlimiting example, when a microbe is captured or bound to the surface of an interdigital finger in the absence of an antimicrobial, the microbe causes a downward frequency shift due to momentum conservation. When this occurs and the microbe is static (e.g., not growing or proliferating), the frequency is constant over time. However, when the microbe is subsequently exposed to an antimicrobial, the microbe experiences a challenge to its metabolism. This may alter the transcription profile of the microbe and actively inhibit cell wall synthesis (for example, particularly in the case of E. coli being susceptible to ampicillin).

The acoustic biosensor described herein is well suited for diagnostic and treatment applications. In particular, the acoustic biosensor can output a value that is indicative of an interaction between a microbial and an antimicrobial. Hence, the acoustic biosensor can output information related to efficacy of the antimicrobial with respect to the microbial. Moreover, the acoustic biosensor described herein exhibits various advantages over conventional technologies used to determine efficacy of an antimicrobial with respect to a microbial. In an example, the acoustic biosensor described herein is deployed “in the field”, such that the acoustic biosensor is not limited to a laboratory environment. Further, the acoustic biosensor is able to output information that is indicative of efficacy of an antimicrobial with respect to a microbial in a relatively short period of time (e.g., within a few hours) instead of requiring several days or even weeks. Still further, the acoustic biosensor is readily manufacturable, as backside etching and release of a thin membrane from a silicon substrate is not required to manufacture the acoustic biosensor.

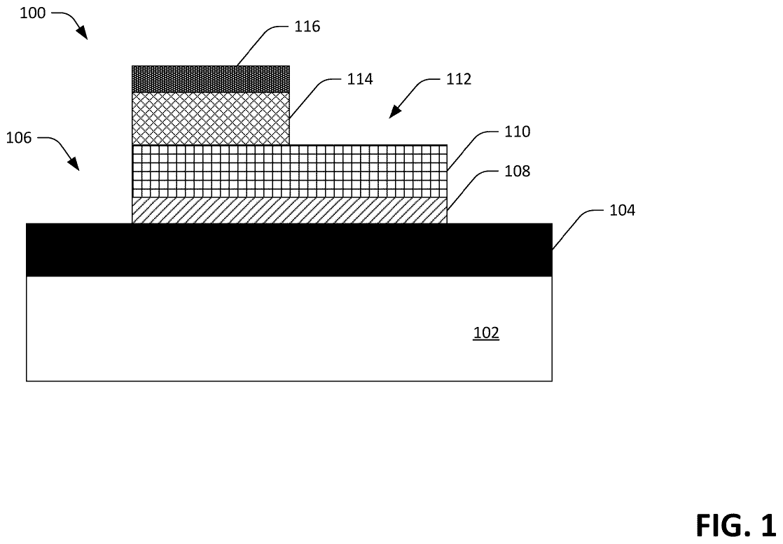

With reference now to FIG. 1, a schematic profile view of an acoustic biosensor 100 is depicted. The acoustic biosensor 100 includes a solid substrate 102; in an example, the substrate 102 is silicon. The substrate 102 has a thickness of between approximately 0.25 millimeters and 1 millimeter. The acoustic biosensor 100 additionally includes a piezoelectric material 104 layered on the substrate 102. In an example, the piezoelectric material 104 is Y-cut lithium niobate. In another example, the piezoelectric material 104 is X-cut lithium niobate. In still yet another example, the piezoelectric material 104 is Z-cut lithium niobate. The piezoelectric material 104 has a thickness of between approximately 1 micron and approximately 20 microns.

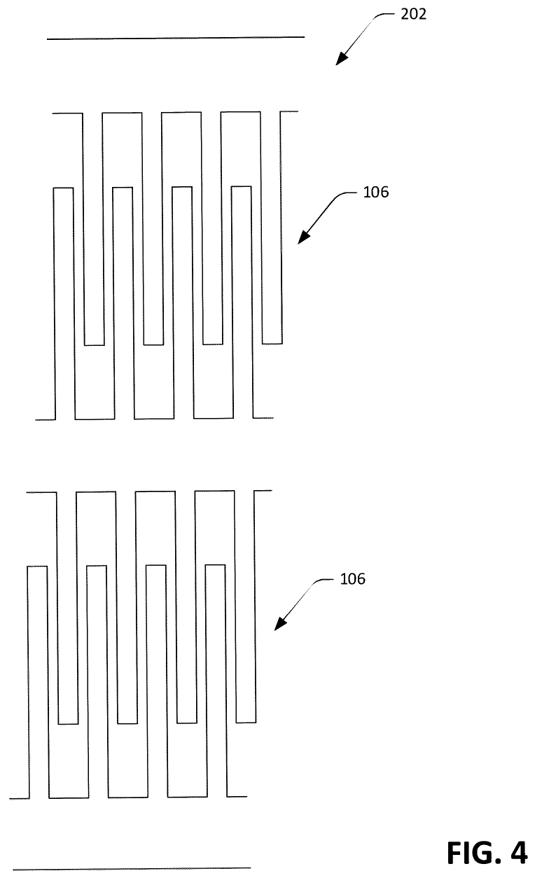

The acoustic biosensor 100 additionally includes a row of metallic interdigital fingers 106 that are formed on the piezoelectric material 104. Referring briefly to FIG. 3, an overhead view of the row of interdigital fingers 106 is presented. Returning to FIG. 1, the row of interdigital fingers 106 can be formed of any suitable conductive metal or combination of metals. In the embodiment presented in FIG. 1, the row of interdigital fingers 106 comprises: 1) a layer of titanium 108 that is mounted on the piezoelectric material 104; and 2) a layer of aluminum 110 that is mounted on the layer of titanium 108. In an example, the layer of titanium 108 is approximately 5 nanometers thick and the layer of aluminum 110 is approximately 80 nanometers thick. An active region 112 of the acoustic biosensor 100 includes a region that comprises the row of interdigital fingers 106 and piezoelectric material 104 underneath the interdigital fingers 106.

The acoustic biosensor 100 also comprises bussing 114 that is mounted to an interdigital finger in the interdigital fingers 106. The bussing 114 can be made of aluminum, some other suitable conductive material, or combination of materials. Optionally, the acoustic biosensor includes a passivation layer 116 of oxide or a polymer-based film placed upon at least one of the interdigital fingers 106 or the bussing 114. In an example, the oxide is one of silicon dioxide or zinc oxide. In another example, the polymer is one of a cyclic olefin copolymer a high or medium molecular weight polyethylene.

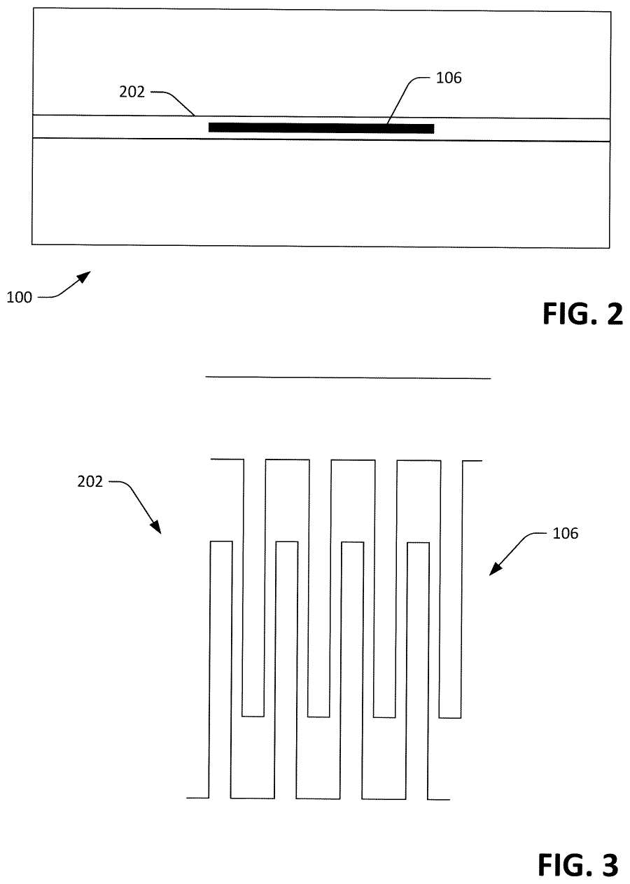

Referring to FIG. 2, an overhead view of the acoustic biosensor 100 is presented. The acoustic biosensor 100 includes a channel 202 that is configured to confine a sample when the sample is introduced to the acoustic biosensor 100; the row of interdigital fingers 106 resides in the channel 202, where the active region comprises the row of interdigital fingers 106 and lithium niobate.

FIG. 3 is an enlarged view of a portion of the channel 202, such that the interdigital figures can be discerned. Generally, width of an individual finger in the interdigital fingers is larger than a space between adjacent interdigital fingers. In an example, width of each finger is between 0.5 um and 1.5 um, with a pitch of between 1 um and 1.5 um. In a specific example, width of each finger is approximately 0.9 um and the pitch is approximately 1.35 um. Moreover, the interdigital fingers include between 20 and 400 pairs of fingers; in an example, the interdigital fingers include approximately 100 pairs of fingers.

Referring briefly to FIG. 4, an enlarged view of another embodiment of a portion of the channel 202 is presented. In the embodiment depicted in FIG. 4, the channel 202 includes two rows of interdigital fingers 106 that extend in parallel with one another, with each row of interdigital finger 106 including between 20 and 400 pairs of fingers. In an example, each finger in each row of interdigital fingers 106 has a width of approximately 0.9 um, and the pitch is approximately 1.35 um.

Operation of the acoustic biosensor 100 is now described. A sample is introduced to the channel 202, which confines the sample to the active region of the acoustic biosensor 100. In an example, the sample includes a microbial. The microbial attaches covalently above the interdigital fingers 106 (through receptors), eventually reaching a steady state. Subsequently, an antimicrobial is introduced to the sample; depending upon efficacy of the antimicrobial, a change may occur in the sample. For instance, the antimicrobial may cause the microbial to release from the surface of the fingers or otherwise degrade, resulting formation of an acoustic mode in the lithium niobate. The acoustic mode travels in the lithium niobate, where the higher acoustic velocity of the underlying silicon relative to the acoustic velocity of lithium niobate assists in causing the lithium niobate to act as a waveguide for the acoustic mode. As lithium niobate is a piezoelectric material, an electrical signal can be read out from the acoustic biosensor 100 by way of an electrode. The electrical signal, over time, is indicative of efficacy of the antimicrobial.

In an example, the sample is in a medium comprising, by way of nonlimiting example, liquid or gas (such as, blood, urine, saliva, water, exhaled breath, mucous, etc.).

By way of nonlimiting example, the microbial comprises at least one of bacteria, fungi, viruses, or parasites. Accordingly, the antimicrobial may comprise at least one of antibiotics, antifungals, antivirals, or anti-parasitics.

In an example, the microbial comprises a gram-negative bacterium.

In an illustrative embodiment, the microbial may comprise a gram-negative bacteria comprising at least one of a species of Acinetobacter (including, but not limited to, Acinetobacter calcoaceticus, Acinetobacter baumannii, and Acinetobacter calcoaceticus-baumanni complex), Bacteroides fragilis, a species of Campylobacter, a species of Citrobacter (including, but not limited to Citrobacter freundii and Citrobacter koseri), Cronobacter, a species of Enterobacterales (including, but not limited to ESBL or CRE, Enterobacter cloacae complex (including, but not limited to Enterobacter cloacae, Enterobacter asbuiae, Enterobacter hormaechei, Enterobacter kobei, Enterobacter ludwigii, and Enterobacter nimipressuralis)), Escherichia coli, Haemophilus influenzae, a species of Fusobacterium (including, but not limited to Fusobacterium nucleatum and Fusobacterium necriphorum), a species of Klebsiella (including, but not limited to, Klebsiella aerogenes, Klebsiella oxytoca, and Klebsiella pneumoniae (including Klebsiella pneumoniae subsp. pneumoniae, Klebsiella pneumoniae subsp. rhinoscleromatis, Klebsiella pneumoniae subsp. ozaenae, or Klebsiella pneumoniae subsp. variicola)), Morganella morganii, a species of Proteus (including, but not limited to, Proteus mirabilis and Proteus vulgaris), a species of Salmonella, a species of Serratia (including, but not limited to, Serratia marcescens), a species of Shigella, Neisseria meningitidis, Pseudomonas aeruginosa, Stenotrophomonas maltophilia, a species of Bacillus (including, but not limited to, Bacillus cereus, or Bacillus subtilis), a species of Corynebacterium, Cutibacterium acnes, a species of Enterococcus (including, but not limited to, Enterococcus faecalis and Enterococcus faecium), a species of Lactobacillus, Listeria monocytogenes, a species of Micrococcus, a species of Staphylococcus (including, but not limited to Staphylococcus aureus, Staphylococcus epidermidis, and Staphylococcus lugdunensis), a species of Streptococcus (including, but not limited to, Streptococcus (GAS) (including Streptococcus pyogenes), Streptococcus (GBS) (including Streptococcus agalactiae), Streptococcus anginosus, and Streptococcus pneumoniae), a species of Carbapenemases, Chlamydia trachomatis, Neisseria gonorrhoeae, Trichomonas vaginalis, Mycoplasma genitalium, or Mycobacterium tuberculosis.

When the microbial is a bacterium, the antimicrobial may comprise at least one antibiotic comprising penicillin, oxacillin, gentamicin, erythromycin, ampicillin, vancomycin, ceftriaxone, meropenem, amikacin, ceftazidime, avibactam, ceftazidime, ciprofloxacin, clavulanic acid, amoxicillin, imipenem, or isoniazid.

In another example, the microbial comprises a fungus comprising at least one of Candida (including, but not limited to, Candida albicans, Candida auris, Candida dubliniensis, Candida famata (AKA: Debaryomyces hansenii), Candida glabrata, Candida kefyr, Candida krusei (AKA: Issatchenkia orientalis), Candida parapsilosis, Candida tropicalis, and Candida guilliermondii), a species of Cryptococcus (including, but not limited to, Cryptococcus neoformans and Cryptococcus gattii), or a species of Rhodotorula (including, but not limited to, Rhodotorula flutinis and Rhodotorula rubra).

When the microbial is a fungus, the antimicrobial may comprise at least one antifungal comprising fluconazole, amphotericin B, or 1-methylimidazole.

In yet another, the microbial comprises a resistance gene. The resistance gene may comprise at least one of IMP, KPC, OXA-48, OXA-23, NDM, VIM, Colistin Resistance, MCR-1, ESBL, CTX-M, Methicillin Resistance, mecA/C, mecA/C and MREJ, Vancomycin Resistance, or vanA/B.

Knowing whether the microbial contains a resistance gene is particularly beneficial when determining which antimicrobial to administer, or whether an antimicrobial will be effective in treating an analyte of interest.

While the examples describe the acoustic biosensor 100 being used in connection with antimicrobial susceptibility testing (AST), it is understood that the acoustic biosensor 100 is also configured to detect biomarkers. Example biomarkers include proteins, peptides, hormones, cytokines, and small-molecule metabolites. By applying a surface coating (such as an antibody film or receptor-specific layer) over the active region, the acoustic biosensor 100 can selectively bind a specific biomarker from a fluid sample (e.g., blood, saliva, or urine). When a biomarker binds to the coated surface, the added mass or structural change generates a measurable shift in the acoustic wave behavior, which is converted into an electrical signal by the piezoelectric material.

This capability enables the acoustic biosensor 100 to detect molecular indicators of disease or physiological state without requiring labeling, amplification, or optical readouts. For example, the acoustic biosensor 100 is functionalized to detect cardiac troponin for myocardial infarction screening, C-reactive protein for inflammation, or specific cytokines for infection or immune response profiling. This makes the acoustic biosensor 100 suitable not only for antimicrobial efficacy testing but also for broader diagnostic use cases in clinical and point-of-care settings.

The acoustic biosensor 100 exhibits various advantages over conventional sensors. Specifically, the acoustic biosensor 100 is readily manufacturable through use of conventional semiconductor manufacturing techniques, without requiring etching from the backside of a silicon wafer or releasing a thin membrane from the silicon wafer. Moreover, the acoustic biosensor 100 exhibits a relatively high quality factor in both air and water. In air, the acoustic biosensor 100 exhibits a quality factor of between 300 and 500. In water, the acoustic biosensor 100 exhibits a quality factor of between 100 and 300. Additionally, the acoustic biosensor 100 exhibits a K2 factor of between 3% and 8%.

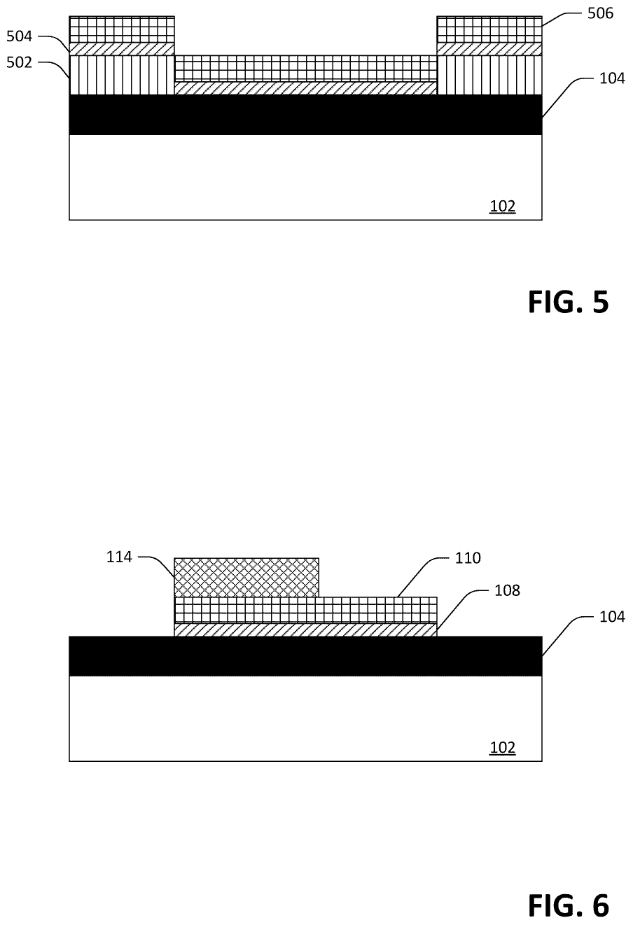

FIGS. 5, 6, and 1 are schematics that collectively illustrate a process for manufacturing the acoustic biosensor 100. With reference solely to FIG. 5, the layer of piezoelectric material (e.g., lithium niobate) 104 is added to the substrate 102. A layer of photoresist 502 is placed on the layer of piezoelectric material 104, and then electron beam lithography is used to remove portions of the photoresist to allow for creation of the interdigital fingers 106 on the layer of piezoelectric material 104. Layers of metal (e.g., a layer of titanium 504 followed by a layer of aluminum 506) are deposited over the remaining photoresist 502 and the exposed layer of piezoelectric material 104.

With reference to FIG. 6, a schematic that depicts further processing of the acoustic biosensor 100 is presented. The acoustic biosensor 100 is patterned, and ion milling is employed to remove native oxides. The bussing 114 is deposited, and liftoff is performed to remove unwanted portions of aluminum and titanium. Returning to FIG. 1, oxides are deposited, and etching is performed to open bond pads.

While the layer of piezoelectric material has been described above as being lithium niobate, in other examples the layer of piezoelectric material is or includes quartz, zinc oxide (ZnO), aluminum nitride (ALN), lithium tantalate (LiTaO3), potassium niobate (KNbO2), langatate (LGT), langanite (LGN), or combinations thereof. Further, while substrate in the acoustic biosensor 100 has been described herein as being silicon, in other examples such is or includes gallium arsenide (GaAs), zinc oxide (ZnO), aluminum nitride (AlN), lead zirconate titanate (PZT), or combinations thereof.

The surface of the piezoelectric material in the acoustic biosensor 100 can be coated with an analyte-specific film that enables selective binding of the microbial and/or antimicrobial. This selective binding enables the acoustic biosensor 100 to detect signaling molecules from the sample that includes the microbial and antimicrobial. In this embodiment, an electrode is still in contact with the layer of piezoelectric material through contact with the coating of analyte specific film.

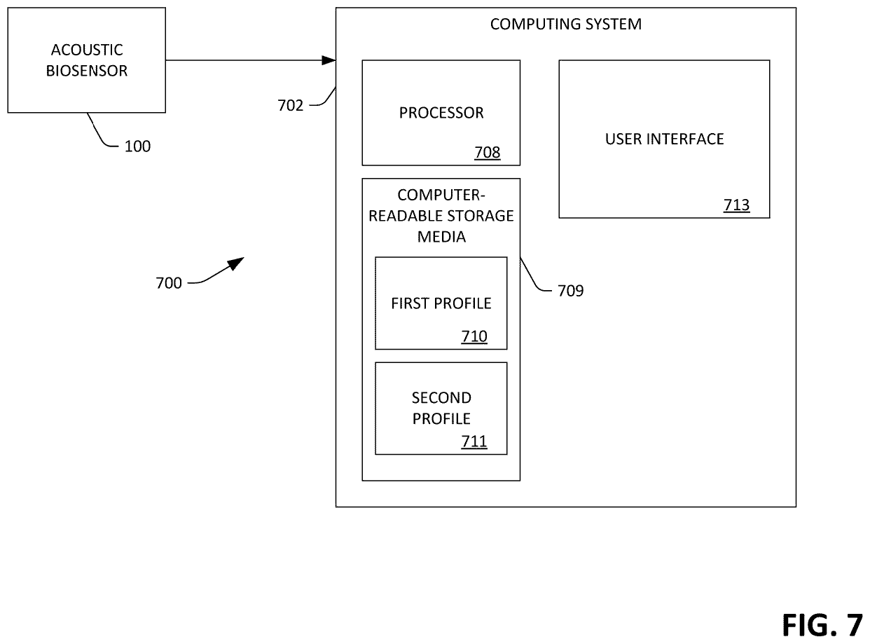

Reference is now made to FIG. 7, which depicts a system 700 that includes the acoustic biosensor 100. The system 700 also includes a computing system 702 that is in communication with the acoustic biosensor 100, where the computing system 702 includes a processor 708 and a non-transitory computer-readable media 709 that is in communication with the processor 708. The processor 708 is further in communication with a user interface 713. The non-transitory computer-readable media 709 stores instructions that, when executed by the processor 708, cause the processor 708 to generate a first profile 710 for a microbial and a second profile 711 based on at least one of a physical or chemical interaction between the microbial and an antimicrobial. The processor 708 outputs an indication that the interaction has occurred by way of the user interface 713. The computing system 702 determines, based on pre-loaded exemplary microbial profiles, what microbial is detected. Subsequent to producing the first profile 710, the computing system 702 can notify a user by way of the user interface 713 as to which microbial(s) have been detected. The system 700 may either automatically deploy antimicrobial(s), or the user may be notified by way of the user interface 713 as to which antimicrobial(s) may be well-suited for treating the microbial. Once the antimicrobial(s) have been deployed, the processor 708 can generate the second profile 711 and cause the second profile 711 to be presented on the user interface 713, where the second profile 711 is indicative of the efficacy of the antimicrobial(s).

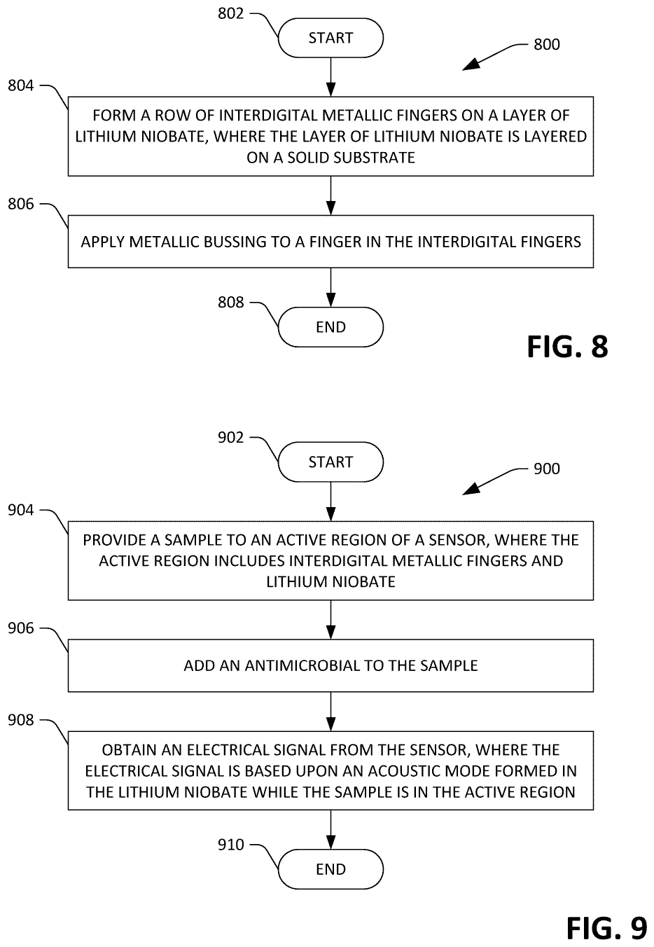

FIGS. 8-9 illustrate methodologies relating to making and using an acoustic biosensor. While the methodologies are shown and described as being a series of acts that are performed in a sequence, it is to be understood and appreciated that the methodologies are not limited by the order of the sequence. For example, some acts can occur in a different order than what is described herein. In addition, an act can occur concurrently with another act. Further, in some instances, not all acts may be required to implement a methodology described herein.

Referring now solely to FIG. 8, a method 800 for making a solidly-mounted lateral field excitation sensor is illustrated. The method 800 starts at 802, and at 804 a row of interdigital metallic fingers is formed on a relatively thin layer of lithium niobate, where the lithium niobate is mounted upon a solid substrate (e.g., a silicon substrate). An active region of the sensor includes the row of interdigital metallic fingers. Optionally, two or more rows of interdigital metallic fingers (with each row being in parallel to one another) can be formed on the layer of lithium niobate.

At 806, aluminum bussing is applied to at least one finger in the interdigital metallic fingers. The method 800 completes at 808.

Now referring to FIG. 9, a method 900 for operating a solidly-mounted lateral field excitation sensor is depicted. The method 900 starts at 902, and at 904 a sample is provided to an active region of the sensor, where the sample includes a microbial, and further where the active region of the sensor comprises a row of interdigital metallic fingers formed on a layer of lithium niobate. The lithium niobate is layered on a solid substrate (e.g., a silicon substrate).

At 906, an antimicrobial is added to the sample. At 908, an electrical signal is obtained from the sensor, where the electrical signal is based upon an acoustic mode generated in the lithium niobate while the sample is in the active region and the antimicrobial is added to the sample. The acoustic mode is indicative of an interaction between the microbial and the antimicrobial in the sample (and is accordingly indicative of efficacy of the antimicrobial with respect to the microbial). The method 900 completes at 910.

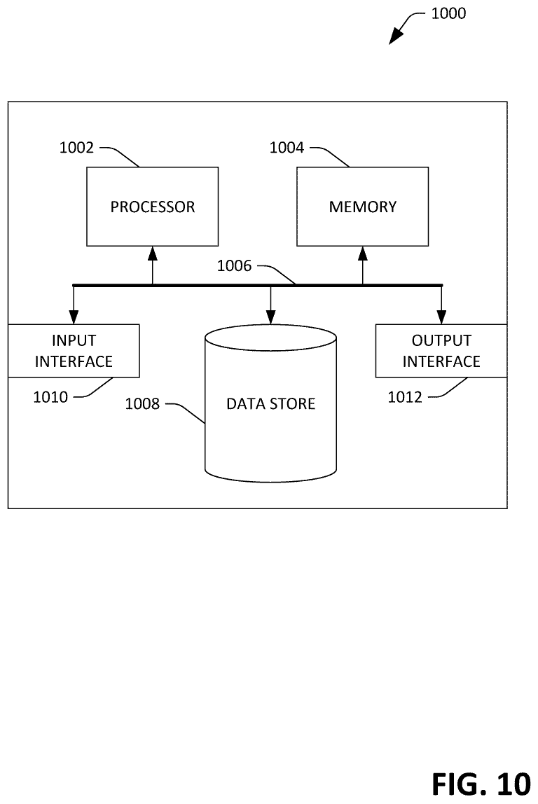

Referring now to FIG. 10, a high-level illustration of an exemplary computing device 1000 that can be used in accordance with the systems and methodologies disclosed herein is illustrated. For instance, the computing device 1000 may be used in a system that is configured to identify a microbial in a sample. By way of another example, the computing device 1000 can be used in a system that identifies a parameter relating to interaction of the microbial with an antimicrobial. The computing device 1000 includes at least one processor 1002 that executes instructions that are stored in a memory 1004. The instructions may be, for instance, instructions for implementing functionality described as being carried out by one or more components discussed above or instructions for implementing one or more of the methods described above. The processor 1002 may access the memory 1004 by way of a system bus 1006. In addition to storing executable instructions, the memory 1004 may also store a profile for the microbial, graphical information, etc.

The computing device 1000 additionally includes a data store 1008 that is accessible by the processor 1002 by way of the system bus 1006. The data store 1008 may include executable instructions, sensed parameters, etc. The computing device 1000 also includes an input interface 1010 that allows external devices to communicate with the computing device 1000. For instance, the input interface 1010 may be used to receive instructions from an external computer device, from a user, etc. The computing device 1000 also includes an output interface 1012 that interfaces the computing device 1000 with one or more external devices. For example, the computing device 1000 may display text, images, etc. by way of the output interface 1012.

Additionally, while illustrated as a single system, it is to be understood that the computing device 1000 may be a distributed system. Thus, for instance, several devices may be in communication by way of a network connection and may collectively perform tasks described as being performed by the computing device 1000.

Various functions described herein can be implemented in hardware, software, or any combination thereof. If implemented in software, the functions can be stored on or transmitted over as one or more instructions or code on a computer-readable medium. Computer-readable media includes computer-readable storage media. A computer-readable storage media can be any available storage media that can be accessed by a computer. By way of example, and not limitation, such computer-readable storage media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, include compact disc (CD), laser disc, optical disc, digital versatile disc (DVD), floppy disk, and Blu-ray disc (BD), where disks usually reproduce data magnetically and discs usually reproduce data optically with lasers. Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio and microwave are included in the definition of communication medium. Combinations of the above should also be included within the scope of computer-readable media.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An acoustic biosensor that is configured to receive a sample that comprises a microbial and an antimicrobial, the acoustic sensor comprising:
a silicon substrate;
a layer of lithium niobate on the silicon substrate;
a first metallic comb structure formed on the layer of lithium niobate; and
a second metallic comb structure mounted on the layer of lithium niobate, where fingers of the first metallic comb structure and the second metallic comb structure are in parallel with one another, and further where the acoustic biosensor is configured to emit an electrical signal based upon an acoustic mode formed in the layer of lithium niobate when at least one of a physical, chemical, or electrical interaction occurs between the microbial and the antimicrobial when the sample is placed in an active region of the acoustic biosensor, and further where the interaction is between a parameter of the microbial and the antimicrobial.

2. The acoustic biosensor of claim 1, where the active region of the acoustic biosensor comprises the first metallic comb structure and the second metallic comb structure.

3. The acoustic biosensor of claim 1, where the lithium niobate is Y-cut lithium niobate.

4. The acoustic biosensor of claim 1, where the lithium niobate is X-cut lithium niobate.

5. The acoustic biosensor of claim 1, where the first metallic comb structure comprises a first finger and a second finger, where the first finger has a width, the first finger is adjacent to the second finger, the first finger is separated from the second finger by a gap, and further where the width of the first finger is larger than the gap.

6. The acoustic biosensor of claim 5, where the second finger has the width.

7. The acoustic biosensor of claim 1, where the first metallic comb structure and the second metallic comb structure comprise at least one of aluminum or titanium, and further where the acoustic biosensor comprises:
bussing that is mounted on the first metallic comb structure; and
a layer of at least one of zinc oxide, silicon dioxide, or a polymer-based film on the bussing.

8. The acoustic biosensor of claim 1, where the layer of lithium niobate has a thickness of between 1 micron and 20 microns.

9. The acoustic biosensor of claim 1, further comprising a third metallic comb structure and a fourth metallic comb structure, where the third metallic comb structure and the fourth metallic comb structure are in parallel with the first metallic comb structure and the second metallic comb structure.

10. The acoustic biosensor of claim 1, where the acoustic biosensor has a quality factor of between 100 and 200 when the acoustic biosensor is placed in water.

11. The acoustic biosensor of claim 1, where the first metallic comb structure and the second metallic comb structure each comprise between 100 and 400 fingers.

12. The acoustic biosensor of claim 1, where the acoustic biosensor is a solidly mounted lateral field excitation sensor.

13. The acoustic biosensor of claim 1, wherein the microbial is a bacteria comprising at least one of a species of Acinetobacter, Bacteroides fragilis, Campylobacter, a species of Citrobacter, Cronobacter sakazakii, a species of Entereobacters, Escherichia coli, Haemophilus influenzae, a species of Fusobacterium, a species of Klebsiella, Morganella morganii, a species of Proteus, Salmonella, a species of Serratia, a species of Shigella, Neisseria meningitidis, Pseudomonas aeruginosa, Stenotrophomonas maltophilia, a species of Bacillus, a species of Corynebacterium, Cutibacterium acnes, a species of Enterococcus, a species of Lactobacillus, Listeria monocytogenes, a species of Micrococcus, a species of Staphylococcus, a species of Streptococcus, a species of Carbapenemases, Chlamydia trachomati, Neisseria gonorrhoeae, Trichomonas vaginalis, Mycoplasma genitalium, or Mycobacterium tuberculosis.

14. The acoustic biosensor of claim 1, wherein the antimicrobial is an antibiotic comprising at least one of penicillin, oxacillin, gentamicin, erythromycin, ampicillin, vancomycin, ceftriaxone, meropenem, amikacin, ceftazidime, avibactam, ceftazidime, ciprofloxacin, clavulanic acid, amoxicillin, imipenem, or isoniazid.

15. The acoustic biosensor of claim 1, wherein the microbial is a fungus comprising at least one of a species of Candida, Cryptococcus, or Rhodotorula.

16. The acoustic biosensor of claim 1, wherein the antimicrobial is an antifungal comprising at least one of fluconazole, amphotericin B, or 1-methylimidazole.

17. A method for operating a solidly-mounted lateral field excitation sensor, the method comprising:
providing a sample to an active region of the sensor, where the active region comprises a row of interdigital metallic fingers mounted on a layer of lithium niobate, where the lithium niobate is on a solid substrate; and
obtaining an electrical signal from the sensor, where the electrical signal is based upon an acoustic mode formed in the layer of lithium niobate while the sample is in the active region, and further where the electrical signal is indicative of existence of a biomarker in the sample.

18. The method of claim 17, where the layer of lithium niobate is Y-cut lithium niobate.

19. The method of claim 17, where the biomarker is one of a protein, a peptide, a hormone, a cytokine, or a metabolite.

20. A method for creating a solidly-mounted lateral field excitation sensor, the method comprising:
forming a row of interdigital metallic fingers on a layer of lithium niobate, where the layer of lithium niobate is mounted upon a solid silicon substrate, and further where an active region of the sensor comprises the interdigital metallic fingers; and
applying metallic bussing to at least one metallic finger in the interdigital metallic fingers.
